(19) United States
(12) Patent Application Publication
(10) Pub. No.: US 2015/0340744 A1
(43) Pub. Date: Nov. 26, 2015

(54) BATTERY CELL HEALTH MONITORING USING EDDY CURRENT SENSING

(71) Applicants: Aaron J. KNOBLOCH, Schenectady, NY (US); Yuri Alexeyevich PLOTNIKOV, Schenectady, NY (US); Christopher James KAPUSTA, Schenectady, NY (US); Jason Harris KARP, Schenectady, NY (US); Yizhen LIN, Schenectady, NY (US)

(72) Inventors: Aaron J. KNOBLOCH, Schenectady, NY (US); Yuri Alexeyevich PLOTNIKOV, Schenectady, NY (US); Christopher James KAPUSTA, Schenectady, NY (US); Jason Harris KARP, Schenectady, NY (US); Yizhen LIN, Schenectady, NY (US)

(21) Appl. No.: 14/667,252

(22) Filed: Mar. 24, 2015

Related U.S. Application Data
(63) Continuation-in-part of application No. PCT/US15/12707, filed on Jan. 23, 2015.
(60) Provisional application No. 61/969,430, filed on Mar. 24, 2014.

(51) Int. Cl. H01M 10/48; G01R 31/36

(52) U.S. Cl. CPC H01M 10/482; G01R 31/3658; G01R 31/3651; H01M 2010/4271

(57) ABSTRACT

The invention provides a battery sensing system comprising a battery module comprising a plurality of battery cells, at least one sensor coil coupled to or placed adjacent to one of more of the plurality of battery cells to determine cell expansion during cell operation, and a battery management system comprising one or more processors and/or microcontrollers that control operation of the plurality of battery cells.

### RELATED APPLICATIONS

This application is a continuation-in-part of International Patent Application No. PCT/US15/12707 filed Jan. 23, 2015 which claims priority to U.S. Provisional Application No. 61/969,430 filed Mar. 24, 2014, the contents of which are hereby incorporated by reference.

### STATEMENT REGARDING FEDERALLY SPONSORED RESEARCH & DEVELOPMENT

This invention was made with Government support under contract number DE-AR0000269 awarded by the Department of Energy. The Government has certain rights in the invention.

### BACKGROUND

Embodiments of the present disclosure relate generally to a method and system for monitoring battery cell health. More specifically, the present disclosure relates to a method and system for monitoring battery cell health using eddy current sensing.

There is an increasing prevalence to provide electrochemical storage devices such as batteries and capacitors in portable power generation from cell phones and laptops to portable power generation such as those found in automobiles and as part of power stations as grid storage. Electric vehicle (EV) packs (whether Plug-in Hybrid electric vehicle (PHEV), Hybrid Electric Vehicle (HEV) or Battery electric vehicle (BEV)) are composed of cells packaged into modules, which may include one or more cells which may further be arranged in one or more modules within a pack. FIG. 1 shows the arrangement of one such module. FIG. 1 shows a battery module 10 and a plurality of battery cells (1-5). The cells can be formed with many different chemistries and have different outer packages including soft pouch cells with a thin electrically conductive outer case (usually in rectangular form) and hard pouch cells with a thicker electrically conductive outer case (either in cylindrical or prismatic (rectangular cross-section)). As an example, FIG. 1 shows prismatic cells (1-5) having a thick electrically conductive outer case. Typically, the hard pouch cells are wrapped with a thin plastic to prevent shorting between adjacent cells.

Many of the EV packs that exist today are designed around their cooling systems. Packs from certain automobile manufacturers use cabin air that flows between the cells to maintain a constant uniform temperature across the cells and cool the cells while others use water routed around the outer portion of the pack to cool the cell. In some implementations, the cells are spaced apart through the use of spacers to keep the cells at fixed gap from one another, which allows flow of cabin air on the surface of the cells. In other implementations, the cylindrical cells are held from above and below to maintain spacing between the cells which allows for the flow of air around the cells.

As cells are charged and discharged, the outer cases of the cells expand and contract due to, for example, the lithiation of the electrodes or as a result of temperature changes that arise within the cell or outside of the cell due to the environment. This expansion is a unique parameter based on the electrode composition and battery chemistry, but is applicable to many battery chemistries including Li-ion batteries. The amount of expansion at any particular State of Charge (SOC) is also a function of the battery temperature and health or remaining life of the battery. In prior work, researchers have examined the deflection of the battery through use of strain gages, neutron scattering measurements of the electrodes themselves or laser based measurements of the deflections of the outside of the cell. However, there has lacked an accurate method to make in-situ measurements of the deflection of the battery when the cell is packaged as part of a pack that would be suitable for field installation either in grid storage or on-road, vehicle applications. Measurements with strain related approaches (such as strain gages or fiber Bragg gratings) could potentially be integrated into a cell or pack to make strain measurements. However, they suffer from several drawbacks. First, they provide an indirect measurement of the deflection of the cell and require the battery system to utilize additional computing power to solve a mechanical model of the cell to determine the electrode displacement from the strain measured on the surface of the cell. This calculation will also incur error on the overall measurement reducing the value of the approach. For optical techniques like fiber Bragg gratings, the cost of the interrogation system would be too high for deployment in cost sensitive applications such as automotive.

Thus, there is need for an improved method and system to monitor the health and life of the battery through direct measurements of expansion of the cell that can be placed in-situ within the pack or group of cells or a single cell.

### BRIEF DESCRIPTION OF THE INVENTION

In accordance with one embodiment described herein, a sensing system is presented.

In one embodiment, the sensing system comprises: a battery module comprising a plurality of battery cells; an eddy current sensor coil placed adjacent to one or more of the plurality of cells to determine cell expansion during cell operation; and a battery management system to control operation of the battery based on the cell expansion.

In one embodiment, the battery management system further comprises one or more controllers to control operation of the battery based on one or more control algorithms.

In one embodiment, the battery cells of the battery sensing system are structured into one or more battery modules, strings or packs.

In one embodiment, the eddy current sensor coil of the battery sensing system is placed between two battery cells to measure expansion in one or both of the battery cells.

In one embodiment, the battery sensing system further comprises a temperature sensor.

In one embodiment, the battery sensing system further comprises a reference coil. In one embodiment, the reference coil may be located adjacent to or near at least one of the battery cells.

In one embodiment, the battery management system further comprises sensor electronics located apart from the battery module and adjacent to the sensor coil. In one embodiment, the reference coil may be located within the sensor electronics.

In one embodiment, the sensor coil and/or reference coil of the battery sensing system is thin and flexible.

### BRIEF DESCRIPTION OF THE FIGURES

These and other features, aspects, and advantages of the present invention will become better understood when the following detailed description is read with reference to the accompanying figures in which like characters represent like parts throughout the drawings, wherein:

FIG. 1 is a perspective view of a battery module comprising a plurality of battery cells in accordance with an embodiment of the invention;

FIG. 2A illustrates an overall system block diagram of a battery sensing system with the reference coil(s) located within the sensor electronics, in accordance with an embodiment of the invention;

FIG. 2B illustrates an overall system block diagram of a battery sensing system with the reference coil(s) located outside of the sensor electronics, in accordance with an embodiment of the invention;

FIG. 3A illustrates a front view of the battery cell and sensor electronics illustrated in FIG. 2A, in accordance with an embodiment of the invention;

FIG. 3B illustrates a front view of the battery cell and sensor electronics illustrated in FIG. 2B, in accordance with an embodiment of the invention;

FIG. 4A illustrates a block diagram of sensor electronics illustrated in FIG. 2A, in accordance with an embodiment of the invention;

FIG. 4B illustrates a block diagram of sensor electronics illustrated in FIG. 2B, in accordance with an embodiment of the invention;

FIG. 5A illustrates the sensor coil and temperature sensor configuration of FIG. 2A, manufactured using flexible substrate processing in accordance with an embodiment of the invention;

FIG. 5B illustrates the sensor coil and temperature sensor configuration of FIG. 2B, manufactured using flexible substrate processing in accordance with an embodiment of the invention;

FIG. 6 illustrates a sensor coil attached to a fixed body adjacent to the battery cell to measure the expansion of the cell in accordance with an embodiment of the invention;

FIG. 7 illustrates a sensor coil attached directly to a battery cell to measure the expansion of the cell in accordance with an embodiment of the invention;

FIG. 8 illustrates a sensor coil attached to a standoff which is attached to a battery cell to measure the expansion of the cell in accordance with an embodiment of the invention;

FIG. 9 illustrates an array of eddy current and temperature sensors integrated within a battery module in accordance with an embodiment of the invention;

FIG. 10 illustrates characteristic sensor output as a function of the gap between the sensor and the cell in accordance with an embodiment of the invention;

FIG. 11 illustrates characteristic sensor output as a function of the gap between the sensor and the cell in accordance with an embodiment of the invention; and

FIG. 12 is a plot illustrating the cell displacement measured by a battery sensing system in accordance with an embodiment of the invention.

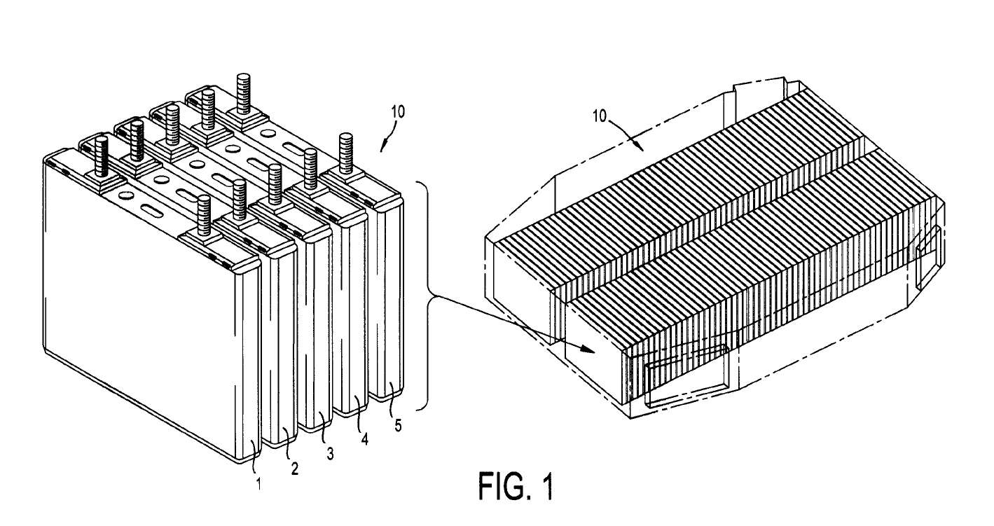

### DETAILED DESCRIPTION

Reference will be made below in detail to exemplary embodiments of the invention, examples of which are illustrated in the accompanying drawings. Wherever possible, the same reference numerals used throughout the drawings refer to the same or like parts.

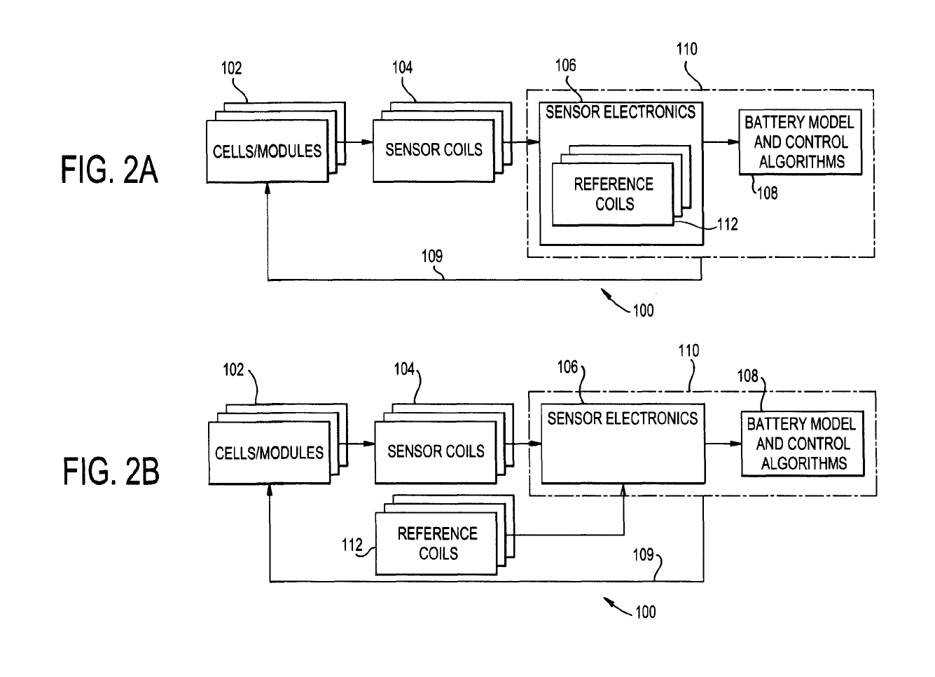

As will be described in detail hereinafter, various embodiments of exemplary structures and methods for monitoring the health and life of the battery through in-situ, direct measurements of expansion of the cell are presented. FIGS. 2A and 2B illustrate an overall system block diagram of a battery sensing system 100 including a pack or group of battery cells or modules 102, and one or more eddy current sensor coils 104 (hereinafter, “sensor coils”) mounted on or substantially near one or more of the cells 102 to detect expansion of the cells 102 in-situ, typically upon operation of the battery. It is noted that the sensor coil(s) 104 do not measure the actual current flow within the battery, but instead measure the expansion (i.e., physical deformation) of the outer wall of the cell 102. Specifically, the voltage output of the sensor coil(s) 104 changes as the cell 102 expands and the gap between the sensor coil 104 and the adjacent cell 102 narrows. The voltage output is then used to determine the amount of physical deformation of the walls of the cell(s) 102. While a plurality of battery cells 102 and sensor coils 104 are illustrated, the battery sensing system 100 may also include one battery cell 102 and one sensor coil 104. In one embodiment, each cell 102 within the group includes a corresponding sensor coil 104, whereas in other embodiments the number of cells 102 and sensor coils 104 may differ. In one embodiment, two or more sensors coils 104 may be utilized to detect expansion of a single cell 102. In one embodiment, the battery cells 102 are formed of lithium-ion batteries.

The battery sensing system 100 of FIGS. 2A and 2B includes a Battery Management System (BMS) 110, which may include sensor electronics 106 and battery model and control algorithms module 108. The sensor electronics 106 controls the powering and reading of the sensor coil(s) 104 as well as the processing and interpretation of the information or signals provided from the sensor coil(s) 104. In one embodiment, the sensor coils 104 may be multiplexed, which enables the battery management system 110, including the sensor electronics 106, to be shared among multiple battery cells 102.

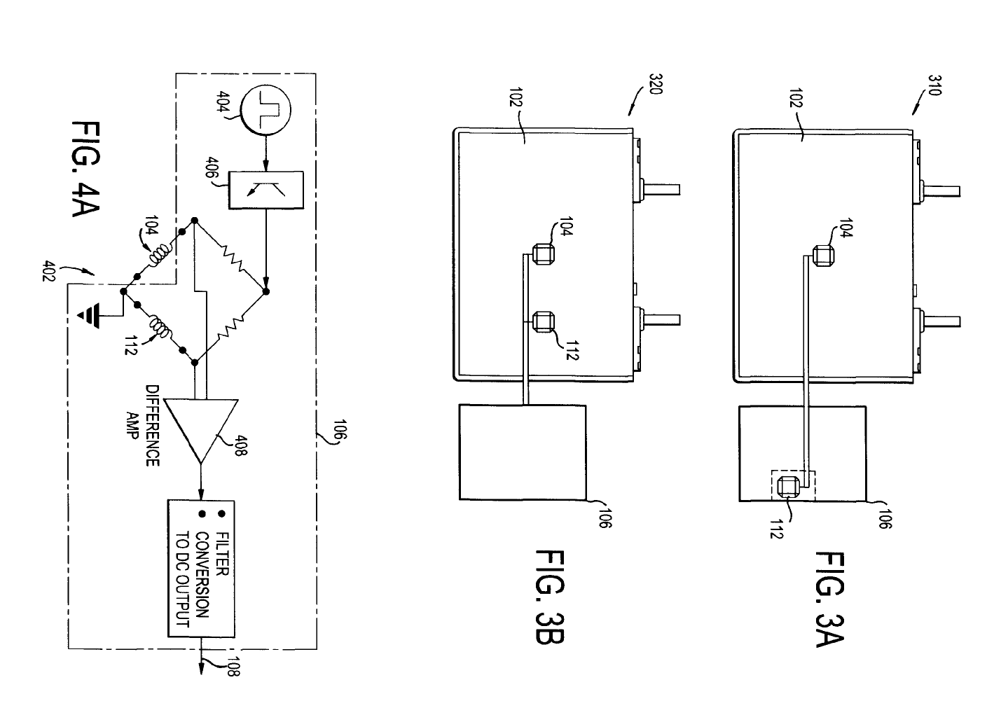

A first embodiment is illustrated in FIGS. 2A and 3A, where the sensor electronics 106 may include at least one reference coil 112. Reference coil(s) 112 are typically identical to the sensor coil 104 in either manufacturing or nominal value of inductance and resistance and are used as a baseline to measure the change in sensed gap between the battery cells 102. Specifically, the reference coil 112 provides a reference voltage which accounts for common mode noise in the system. In operation, the reference coil 112 accounts for common mode noise, where environmental changes that would affect both the sensor coil 104 and the reference coil 112, such as a temperature change, would not cause a change in the difference of the signals. As such, the reference coil 112 remains at a fixed position that does not move, while the sensor coil 104 is affected by displacement of the battery cell 102. In one embodiment as discussed herein, the sensor coil 104 is positioned on the wall of the cell 102, such that it is displaced as the wall of the cell 102 is deformed. The differential measurement between the voltage output of the reference coil 112 and the voltage output of the sensor coil 104 is used to calculate displacement of the cell 102. In this first configuration 310, as illustrated in FIG. 3A, the reference coil 112 is integrated within the sensor electronics 106. In this configuration, the reference coil 112 does not directly detect the cell expansion during charge and discharge, but is located remotely in the sensor electronics 106, which is part of the BMS 110.

A second embodiment is illustrated in FIGS. 2B and 3B, where the reference coil(s) 112 may be located outside of the sensor electronics 106 and in proximity to the sensor coil(s) 104 so that it experiences the same environmental changes as the sensor coil(s) 104. In this second configuration 320, as illustrated in FIG. 3B, the reference coil 112 is disposed on or near a cell 102 in an area where the wall of the cell 102 is not moving relative to the reference coil 112 during charge or discharge, and thus not modulating the reference coil 112. For instance, the reference coil 112 can be built on the same substrate as sensor coil(s) 104, but spaced apart from sensor coil(s) 104. The reference coil 112 can be placed adjacent to the sensor coil(s) 104, though the distance to the battery cell 102 must be held constant so as to not be affected by displacement changes of cell 102, which would negate the changes sensed by the sensor coil 104. One method of doing so is to mount the reference coil 112 directly to the surface of the battery cell 102 where a conductive casing is present such that the reference coil 112 is saturated. Another method is to place the reference coil 112 elsewhere, such that the wall of the cell 102 is outside the range of sensitivity (typically >1 mm) of the reference coil 112.

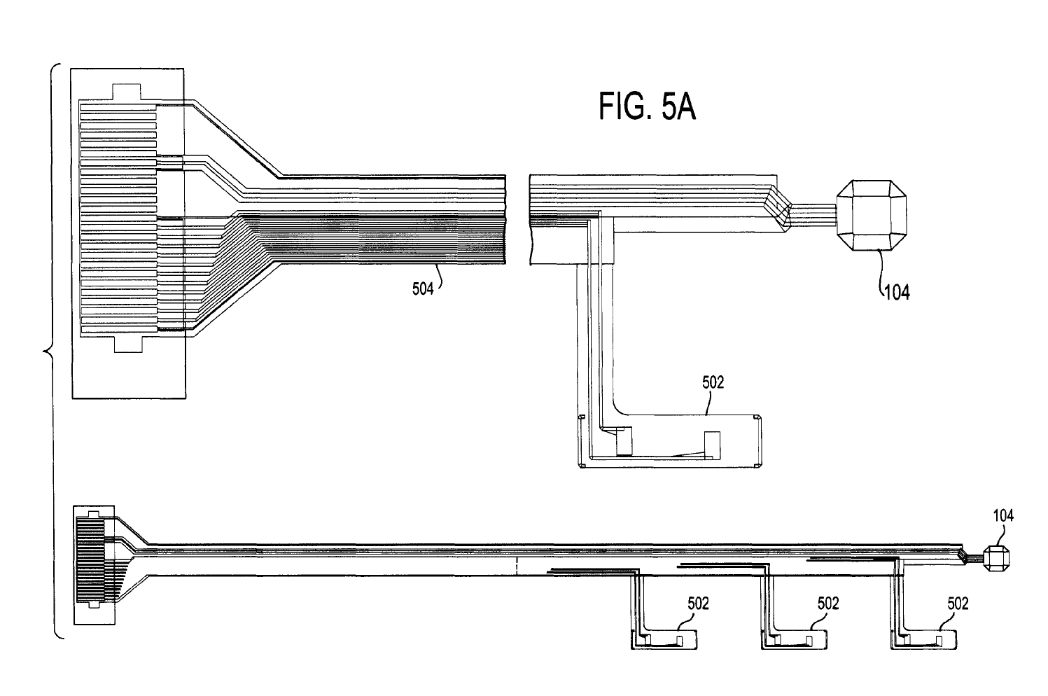

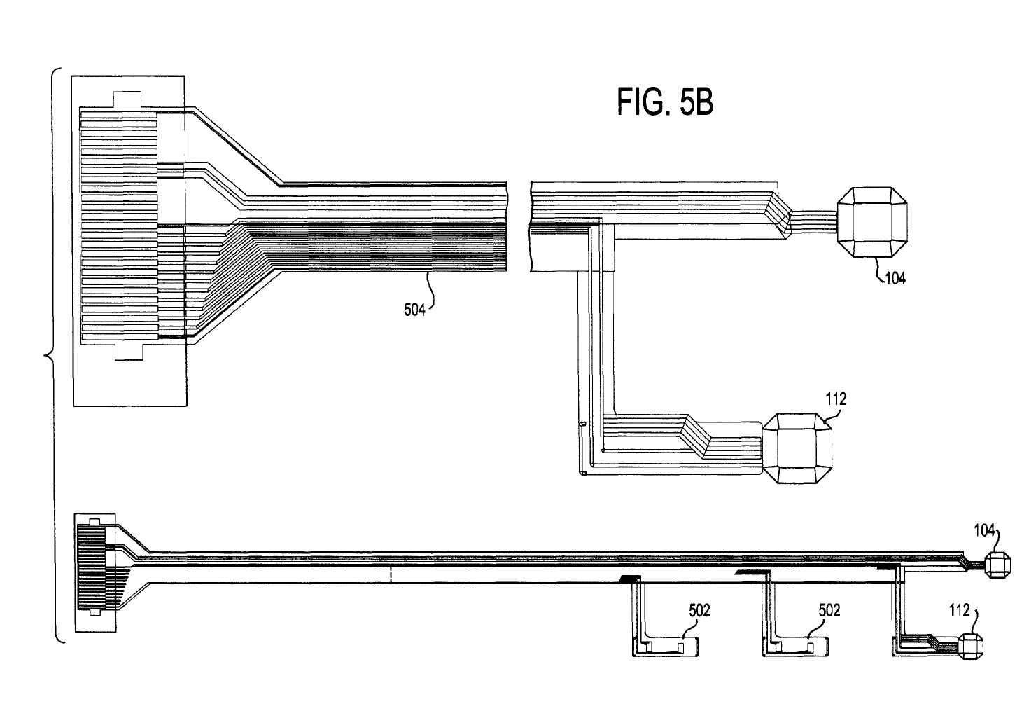

The interpretation of the information or signals provided from the sensor coil(s) 104 may include statistical analysis of the data, comparisons to historical values, comparisons to other sensor coils in the battery pack and application of calibrations. The sensor electronics 106 may represent one or more processors, or microcontrollers to perform the functions listed. The information from the sensor coil(s) 104 is passed from the sensor electronics 106 to the battery model and control algorithms module 108. The battery model and control algorithms module 108 may represent one or more processors or microcontrollers configured to execute programming instructions or control algorithms to control operation of one or more cells 102. In at least one embodiment, the processors or microcontrollers used to form the sensor electronics 106 can be the same as the processors or microcontrollers for the battery model and control algorithms module 108. In addition, temperature sensors (see FIGS. 5A and 5B) can be provided as inputs to the sensor electronics 106 to determine expansion based on lithiation and expansion based on temperature changes of the cell 102. Further, the BMS 110 may include at least one storage or memory device to store the data.

In one embodiment, continuous signals are transmitted from the sensor coil(s) 104 to the BMS 110 where they are analyzed by the sensor electronics 106 and used as input to a battery control model 108 for the associated battery pack. Such battery control models 108 may include physics based models of the cell or pack operation, equivalent circuit models of the cell or pack operation, or statistical based analysis of the measurements examining changes in values over time. Based on the input signals from the sensor coil(s) 104, the BMS 110 can send control commands 109 to effect changes in the operation of the battery cells/modules 102. While FIGS. 2A-B show the sensor electronics 106 as being part of the BMS 110, in other embodiments the sensor electronics 106 could be integrated as part of the sensor coil(s) 104 proximal to the sensed location rather than located remotely in the BMS 110. For example, the sensor electronics 106 could be located on another position on the battery cell 102, connected to the sensor coil(s) 104 and/or reference coil(s) 112 via a wire harness or wire leadout (not shown). Moreover, other embodiments may involve the use of additional volatile or non-volatile memory as part of the BMS 110 or sensor electronics 106 such that expansion measurements could be kept and downloaded to analyze the cell and pack abuse levels.

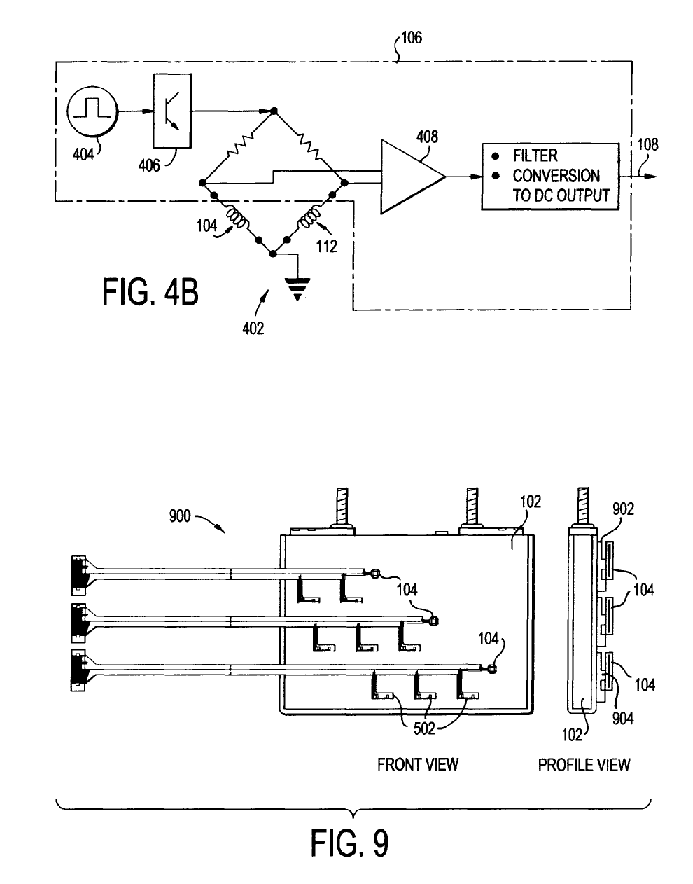

FIGS. 4A and 4B illustrate a schematic block diagram of the sensor electronics 106 in accordance with various embodiments of the invention. As shown in FIG. 4A, the reference coil 112 is located within the sensor electronics, as illustrated in FIGS. 2A and 3A. As shown in FIG. 4B, the reference coil 112 is outside of the sensor electronics, as shown in FIGS. 2B and 3B. As shown in both embodiments, the sensor coil 104 and reference coil 112 may be placed in a voltage differential bridge circuit configuration 402. In the illustrated embodiment, the signals read by the sensor coil 104 may be read through the bridge circuit 402. The signals may vary according to the gap between the sensor coil 104 and one or more of the cells 102. The bridge circuit 402 is driven by an oscillator 404, typically coupled to a current amplifier 406 to generate an AC current and subsequent magnetic field at each of the sensor coil 104 and reference coil 112. The voltages at the center of each bridge arm are passed to a differential amplifier 408 which is only sensitive to the bridge imbalance, and the signals are then filtered, converted to DC output and sent to the battery model and control algorithms module 108. Changes in the oscillator frequency, current amplification, filter and coil geometry can be tuned to change performance characteristics of the complete sensing system. These characteristics can include the sensor range, voltage output, measurement sensitivity (Volts per microns of expansion), and resolution, amongst others. The use of the bridge circuit 402 is advantageous because it allows for a high level of sensitivity to changes in the gap between cells 102. The bridge circuit 402 also provides robustness against environmental changes imposed on the sensor coil 104 and reference coil 112, such as changes in the surrounding temperature. Alternatively, measurements could be made without the use of the bridge circuit 402 or through other readout configurations known in the art, including quadrature measurement of amplitude and phase or frequency modulation.

As shown in FIGS. 5A and 5B, temperature sensor(s) 502 can be located adjacent and proximal to the sensor coil(s) 104 to monitor the temperature of the cell, as well as provide temperature compensation of signal in the sensor electronics 106. Specifically, the temperature sensor(s) 502 may be utilized in situations where the temperature around the sensor coil(s) 104 is changed, but temperature around the reference coil 112 is not exposed to the same environment. In this embodiment, a calibration of the gap between the cells 102 and the voltage output of the sensor coil(s) 104 at various temperatures is performed and integrated into the sensor electronics 106. The temperature sensor 502 may have a thickness of 125 μm or less and can be an RTD or thermocouple. In another embodiment, the temperature sensor 502 can be located directly on at least one of the battery cells 102. In one embodiment, the temperature sensor 502 can be constructed on the same substrate as the sensor coil 104 (on the battery cell 102) so that the temperature sensor information can be used to compensate the sensor output for changes in the temperature of cell 102 which could cause expansion of the battery that would not be indicative of the battery health. In another embodiment, the temperature sensor 502 may also be co-fabricated with the sensor coil(s) 104 to allow for multiple measurement modalities to exist on a common substrate and provide localized temperature compensation signals, as well as accurate temperature monitoring of the battery cell 102.

As illustrated in FIG. 5A, which corresponds to the configuration of FIGS. 2A and 3A, conductive interconnect lines 504 carry the signal from the sensor coil(s) 104 to the sensor electronics 106 (not shown). In one embodiment, the conductive interconnect lines 504 may be in the form of a wire harness. As illustrated in FIG. 5B, which corresponds to the configuration of FIGS. 2B and 3B, the reference coil 112 is located outside of the sensor electronics 106 proximal to the sensor coil 104. In this embodiment, temperature sensor(s) 502 may also be present.

In one embodiment, the sensor coil(s) 104 and the reference coil(s) 112 may be manufactured using flexible substrate processing. In one embodiment, the sensor coil(s) 104 may be fabricated using thin film fabrication techniques. While the sensing coil(s) 104 may be fabricated through several different means, thin-film fabrication provides flexible sensors which can be integrated into the confined spaces between battery cells 102. Coils made through thin-film fabrication can be made to be 100 μm or less in total thickness which allows for placement in the tight packaging constraints of modern energy storage systems, such as vehicles. Further, the entire battery sensing system 10 can be tailored to specific installation applications, and sensor coil(s) 104, reference coil(s) 112, and temperature sensor(s) 502 can be placed in various locations on the battery cell 102.

The substrate of the sensor coil(s) 104, reference coil(s) 112, and temperature sensor(s) 502, and their associated conductors (such as conductive interconnect lines 504), can be made with a variety of metal or electrically conductive materials. For example, sensor coil(s) 104 may be formed using copper. The coils can be of a variety of diameters, such as 3 mm or 4 mm in diameter, and can be circular or square or other geometric shape. In one embodiment, the sensor coil(s) 104 can have a cross-sectional thickness of about 100 um. In one embodiment, the sensor coil(s) 104 are driven at frequencies of approximately 2 MHz which balances a tradeoff between the eddy current generation of the sensor coil 104 and losses within conductive interconnect lines 504. The sensor coil(s) 104 have self-resonant frequencies of greater than about 50 MHz, and the AC drive signal is operated at frequencies far away from this resonance. The drive frequency can be varied based on the sensing application and its requirements. In one embodiment, the total thickness of the sensor coil(s) 104 is minimized to be as small as 50-100 um thick. The ability to build sensors in a package this thin and flexible allows for the integration of these sensors into the highly compact packages of capacitors or battery packs, including those used in automotive, portable power generation, utility, large ships or aircraft applications. The compact size and high operating frequency enables fast output responses for in-situ monitoring.

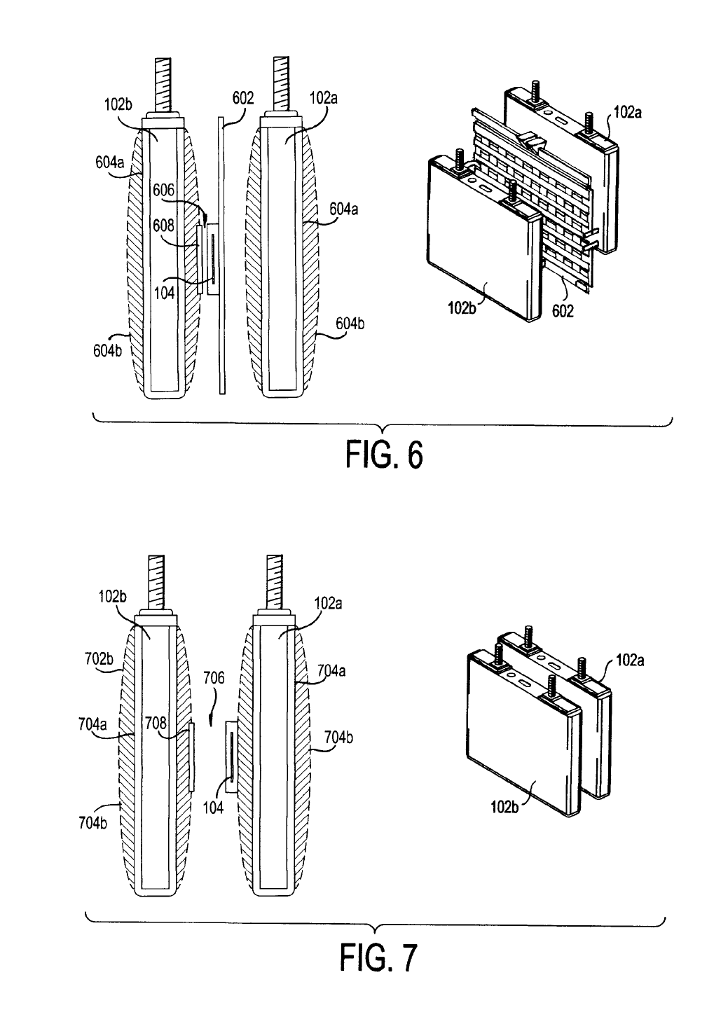

One embodiment of the integration of the sensor coil(s) 104 within battery cells 102 is illustrated in FIG. 6. The cells 102a and 102b of FIG. 6 have prismatic cell geometry, although similar techniques can be employed for cylindrical cell geometries. In this embodiment, the cells 102a and 102b are separated physically with a fixed structural member, such as a plastic spacer or frame 602, which allows for air flow between the cells 102a and 102b, but also allows for the cells 102a and 102b to be compressed as part of the pack or group of cells 102. The sensor coil 104 can be mounted on the plastic frame 602 such that a gap 606 between the sensor coil 104 and the cell 102b is within the sensitive regime of the sensor coil 104. In this embodiment, the plastic frame 602 is approximately 3 mm in thickness and the position of the sensor coil 104 is such that the adjacent cell 102a is outside the sensitive regime of the sensor coil 104. The sensor coil turns are parallel to the plane of the plastic frame 602 so that the sensor coil 104 is also parallel to the surface of each cell 102a and 102b. It is desirable for the mechanism holding the sensor coil 104 to the frame 602, as well as the frame 602, be stable and not move with respect to the cell 102b during operation. The frame 602 is preferably made of an electrically insulating material, such as plastic, so that the sensor coil(s) 1-4 is not in direct electrical contact with the case of the battery cell 102. Other structures known in the art may be used to hold the sensor coil 104 between adjacent cells 102a and 102b. The thinness of the sensor coil 104 allows for mounting the sensor coil 104 without interfering with the cooling flow moving orthogonally with respect to the length of the cells 102a and 102b.

During the operation of the cells 102, the outer portion of the cell case deforms from position 604a to position 604b, changing the spacing (i.e., width of the gap 606) between the sensor coil 104 and cell 102b. The cells 102a and 102b in this embodiment can have an electrically conductive case, such as a metallic case, or a polymeric case with a thin metal reflector or foil 608 to allow for the eddy current measurement. Eddy current sensing requires an electrically conductive surface to generate mutual inductance, hence the ability to measure deflection (position 604) of the outer case of the battery cell 102a and 102b. However, if the sensor coil 104 comes into direct contact with the battery casing, the output may become saturated. FIG. 6 shows the sensor coil 104 situated away from the cell case (˜500 μm) and detects small expansions during cell operation from position 604a to position 604b. Thus, as the case of the cell 102 moves from position 604a to position 604b, the gap 606 between the foil 608 and the sensor coil 104 gets smaller and the voltage output of the sensor coil 104 changes, while the voltage output of reference coil 112 stays the same. As such, the displacement of the cell wall can be determined using, e.g., a calibration curve, calibration formulation, or lookup table.

Another embodiment of the integration of the sensor coil 104 within a module of battery cells 102 is illustrated in FIG. 7. Here, the sensor coil 104 is shown mounted directly on the wall 702 of the cell 102a. When cells 102a and 102b expand from position 704a to position 704b during use, the cell walls 702a and 702b move closer to each other, thus making the gap 706 smaller. In this embodiment, the sensor coil 104 is designed such that it is sensitive in the range of the gap 706 between the cells 102a and 102b through modification of the driving frequency, coil geometry or material choices. In the illustrated embodiment, the gap 706 may be 1-3 mm, however, other gap distances are contemplated. In this embodiment, the cells 102a and 102b are formed of a non-conductive casing material, which allows the sensor coil 104 to be directly mounted to the wall 702 of cell 102a without causing saturation. As in FIG. 6, a thin metal reflector or foil 708 is mounted on the wall of adjacent cell 102b to allow for eddy current measurement as set forth above.

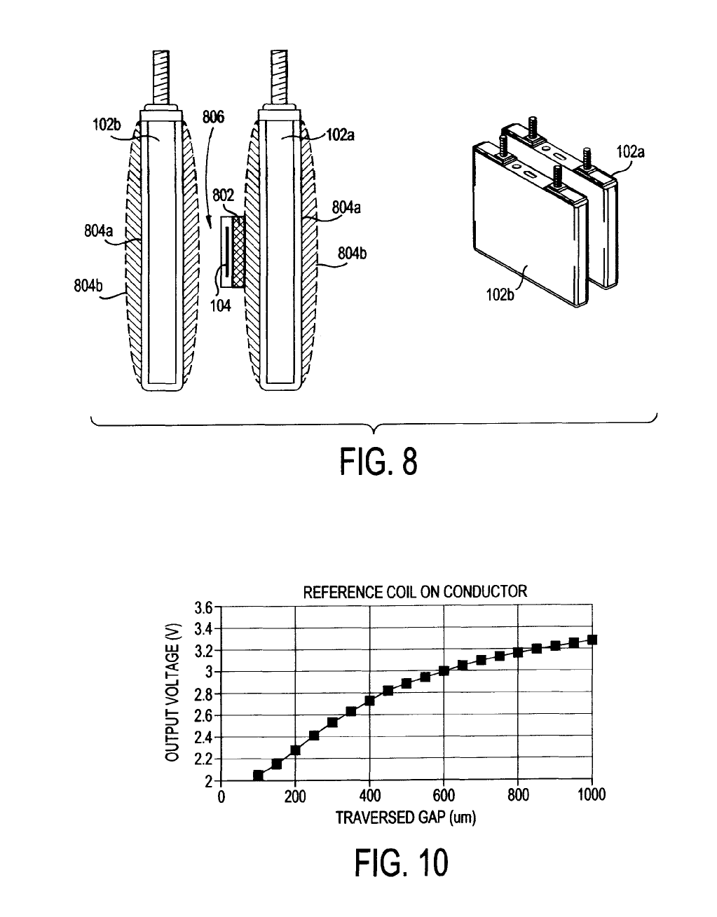

Yet another embodiment of the integration of the sensor coil 104 within a module of battery cells 102 is illustrated in FIG. 8. Here, the sensor coil 104 is mounted on cell 102a on a standoff 802 formed of a non-electrically conductive material, such as a ceramic or plastic. In this way, the sensor coil 104 is not driven into saturation by being mounted directly to the wall of cell 102a, which may be formed of a conductive casing material. As cells 102a and 102b expand from position 804a to position 804b during use, the gap 806 gets smaller and sensor coil 104 is moved closer to adjacent cell 102b. The gap 806 is in the sensitive regime of the sensor coil 104, such that the differential voltage of the sensor coil 104 and reference coil 112 may be determined in order to determine displacement of the cell wall. Thin-film ferrite absorbers (not shown) may also be used to suppress the magnetic field generated by the side of the sensor coil 104 mounted to the wall of the cell 102a.

In FIGS. 3A and 3B, individual measurements of cell deflection have applied individually to each cell 102. As illustrated in FIG. 9, an array 900 of sensor coils 104 and temperature sensors 502 can take multiple measurements of deflection and temperature across the surface of a cell 102 to look at differences in the expansion across the cell surface. Individual outputs can share the same sensing electronics 106 (not shown) through the use of a multiplexer, as discussed above. The arrangement of the temperature sensors 502 is not limited, and they can be placed at a variety of positions as shown. Although in the illustrated embodiment a prismatic cell is shown, the sensor coils 104 could instead be curved and used to measure the deflection of a cylindrical cell. Also shown as part of this embodiment are temperature sensors 502 to take temperature measurements that could be made across the surface in tandem with the measurements of cell expansion. Because of the flexibility of the substrate 902, the surface of the substrate 902 can conform to provide the gap necessary for the sensor coils 104 to measure the displacement of the cells 102. The substrate 902 also makes contact with the cell 102, which allows the temperature sensor 502 to accurately read the temperature of the operating cell. As shown in the profile view of FIG. 9, the flexible substrate 902 may be formed with a standoff 904 that extends outward from the surface of the cell 102. The sensor coils 104 may be attached to the standoffs 904. The bottom portion of the substrate 902 can also be flat and the temperature sensors 502 may be attached thereto adjacent to the wall of the cell 102. The standoffs 902 integrally couple the top portion (where the sensor coils 104 are attached) with the bottom portion (where the temperature sensors 502 are attached). In this way, the temperature sensor 502 can directly contact the cell 102, while the standoff 902 forms a gap between the sensor coil 104 and the cell 102. The sensor coils 104 can then be used to measure cell expansions of an adjacent cell. A common reference coil (not shown in FIG. 9), such as those discussed herein, can also be used when having multiple sensors on a particular cell or multiple sensors across a pack and the sensor electronics 106 could be multiplexed to reduce cost.

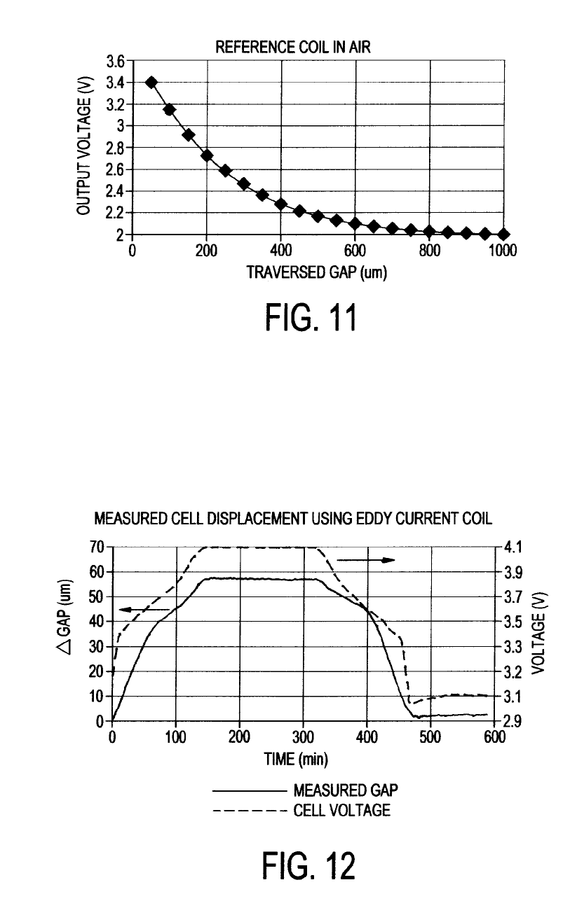

In operation, each sensor coil 104 would have a characteristic response curve that is a function of the drive frequency, coil geometry (size and shape of coil) and the material of the cell case. FIG. 10 shows an example of such a response curve for configuration 310 as illustrated in FIG. 3A. The advantage of configuration 310 is that the reference coil 112 resides in an environment that closely resembles the environment of the sensor coil 104 and more effectively removes potential common mode noise sources, as set forth above. As seen in FIG. 10, the voltage response to a changing gap (such as gap 606, 706 or 806 of FIGS. 6-8) is largely non-linear. In one embodiment, the sensor coil 104 is designed such that it is sensitive in a region between approximately 200 μm and 1000 μm. This regime can be modified through changes in the dimensions of the sensor coil 104 as well as the drive voltage of the sensor coil 104. The response plot of FIG. 11 corresponds to configuration 320 (FIG. 3B). From this plot, it can be seen that the response as a function of gap is also substantially non-linear. Here, the sensor coil 104 and reference coil 112 may be less effective in removing common mode sources of error and the output is more sensitive to expansion of the cell 102. On the other hand, this configuration 320 may be easier to implement in a final application.

FIG. 12 shows the response of the sensor coil 104 when monitoring a prismatic, rectangular hard metallic case cell during a 0.4 C charge and discharge cycle. The upper curve shows the voltage rise during charge and the voltage decrease as the cell is being discharged. Between charge and discharge, there is a 3 hour dwell to let the cell equilibrate. The lower curve shows the sensor coil response using the electronics and linearization detailed previously. The sensor coil 104 is sensitive to expansion changes on the order of 1 μm while being situated about 500 μm from the cell surface in this embodiment.

Certain embodiments contemplate methods, systems and programming instructions or data encoded on machine-readable media to implement functionality described above. Certain embodiments may be implemented using an existing computer processor, or by a special purpose computer processor incorporated for this or another purpose or by a hardwired and/or firmware system, for example. Certain embodiments include computer-readable media for carrying or having computer-executable instructions or data structures stored thereon. Such computer-readable media may be any available media that may be accessed by a general purpose or special purpose computer or other machine with a processor. By way of example, such computer-readable media may comprise RAM, ROM, PROM, EPROM, EEPROM, Flash, CD-ROM or other optical disk storage, magnetic disk storage or other magnetic storage devices, or any other medium which can be used to carry or store desired program code in the form of computer-executable instructions or data structures and which can be accessed by a general purpose or special purpose computer or other machine with a processor. Combinations of the above are also included within the scope of computer-readable media. Computer-executable instructions comprise, for example, instructions and data which cause a general purpose computer, special purpose computer, or special purpose processing machines to perform a certain function or group of functions.

Generally, computer-executable instructions include routines, programs, objects, components, data structures, etc., that perform particular tasks or implement particular abstract data types. Computer-executable instructions, associated data structures, and program modules represent examples of program code for executing steps of certain methods and systems disclosed herein. The particular sequence of such executable instructions or associated data structures represent examples of corresponding acts for implementing the functions described in such steps.

Embodiments of the present disclosure may be practiced in a networked environment using logical connections to one or more remote computers having processors. Logical connections may include a local area network (LAN) and a wide area network (WAN) that are presented here by way of example and not limitation. Such networking environments are commonplace in office-wide or enterprise-wide computer networks, intranets and the Internet, and may use a wide variety of different communication protocols. Those skilled in the art will appreciate that such network-computing environments will typically encompass many types of computer system configurations, including personal computers, handheld devices, multi-processor systems, microprocessor-based or programmable consumer electronics, network PCs, minicomputers, mainframe computers, and the like. Embodiments of the disclosure may also be practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of ordinary skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” etc. are used merely as labels, and are not intended to impose numerical or positional requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose several embodiments of the invention, including the best mode, and also to enable any person of ordinary skill in the art to practice the embodiments of invention, including making and using any devices or systems and performing any incorporated methods. The patentable scope of the invention is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A battery sensing system comprising:
a battery module comprising a plurality of battery cells;
at least one sensor coil coupled to or placed adjacent to one of more of the plurality of battery cells to determine cell expansion during cell operation; and
a battery management system comprising one or more processors and/or microcontrollers that control operation of the plurality of battery cells.

2. The battery sensing system according to claim 1, further comprising a plurality of spacers or a frame placed between each of the plurality of battery cells so as to form a gap therebetween.

3. The battery sensing system according to claim 2, wherein the at least one sensor coil is mounted adjacent to one of the plurality of battery cells on a fixed structural member such that the gap between the at least one sensor coil and the one battery cell is within a sensitive regime of the at least one sensor coil.

4. The battery sensing system according to claim 1, wherein the at least one sensor coil is placed between two of the plurality of battery cells to measure expansion in at least one of the plurality of battery cells.

5. The battery sensing system according to claim 1, wherein each of the plurality of battery cells has either prismatic or cylindrical cell geometry.

6. The battery sensing system according to claim 1, wherein the plurality of battery cells are structured into one or more battery modules.

7. The battery sensing system according to claim 1, further comprising memory integrated within or outside of the battery management system in order to store data signals transmitted from the plurality of battery cells.

8. The battery sensing system according to claim 1, wherein a first portion of the one or more processors and/or microcontrollers of the battery management system form sensor electronics and a second portion of the one or more processors and/or microcontrollers perform battery model and control algorithms.

9. The battery sensing system according to claim 8, wherein the sensor electronics control the powering and reading of the at least one sensor coil and the processing and interpretation of data signals provided from the at least one sensor coil.

10. The battery sensing system according to claim 8, wherein the second portion of the one or more processors and/or microcontrollers execute programming instructions and/or control algorithms to control operation of the plurality of battery cells.

11. The battery sensing system according to claim 9, wherein the data signals are transmitted from the at least one sensor coil to the battery management system where they are analyzed by the sensor electronics.

12. The battery sensing system according to claim 8, wherein the sensor electronics may be integrated within or outside of the battery management system or may be physically integrated with the at least one sensor coil.

13. The battery sensing system according to claim 9, wherein the data signals provided from the at least one sensor coil are read through an inductive bridge circuit having a fixed reference coil.

14. The battery sensing system according to claim 13, wherein the at least one sensor coil and reference coil are manufactured of electrically conductive materials.

15. The battery sensing system according to claim 13, wherein the at least one sensor coil and fixed reference coil are fabricated on a thin, flexible dielectric material.

16. The battery sensing system according to claim 15, wherein the thin, flexible dielectric material is polyimide film.

17. The battery sensing system according to claim 13, wherein the fixed reference coil is disposed on or near at least one of the plurality of battery cells or is configured within the sensor electronics.

18. The battery sensing system according to claim 1, further comprising a temperature sensor.

19. The battery sensing system according to claim 18, wherein the temperature sensor is adjacent to or integrated within the at least one sensor coil.

20. The battery sensing system according to claim 18, wherein the temperature sensor is less than 125 μm in thickness.

21. The battery sensing system according to claim 1, wherein each of the plurality of battery cells has a metallic case or a polymeric case with a thin metal coating.

22. The battery sensing system according to claim 1, wherein the battery sensing system comprises a plurality of sensor coils and temperature sensors positioned in at least one array.

23. The battery sensing system according to claim 1, wherein each of the plurality of battery cells has at least one cell wall and the at least one sensor coil can be used to measure expansions of the at least one cell wall of 1 to 500 μm.

24. The battery sensing system according to claim 1, wherein at least one of the plurality of battery cells is a lithium-ion battery.

25. The battery sensing system according to claim 1, further comprising a gap between the at least one sensor coil and a cell wall of at least one of the battery cells, the system determining a distance of the gap.

26. A method of measuring battery cell expansion comprising the steps of:
a) providing a battery sensing system comprising:
i. a battery module comprising a plurality of battery cells,
ii. at least one sensor coil coupled to or placed adjacent to one of more of the plurality of battery cells, and
iii. a battery management system comprising one or more processors and/or microcontrollers,
b) activating the at least one sensor coil so as to detect expansion of each of the plurality of battery cells while the battery module is in operation;
c) transferring data signals corresponding to the expansion of each of the plurality of data cells from the at least one sensor coil to the battery management system where the data signals are analyzed;
d) communicating with a portion of the one or more processors and/or microcontrollers to control operation of the battery module using algorithms based on the analyzed data signals.
